(19) United States
(12) Patent Application Publication
(10) Pub. No.: US 2011/0168254 A1
(43) Pub. Date: Jul. 14, 2011

(54) Electrode Plate And Dye-Sensitized Photovoltaic Cell Having The Same

(75) Inventors: Yoon Gyu Lee, ChungCheongNam-Do (KR); Yil Hwan You, ChungCheongNam-Do (KR); Dong Jo Kim, ChungCheongNam-Do (KR); Tae Hwan Yu, ChungCheongNam-Do (KR); Sang Cheol Jung, ChungCheongNam-do (KR); Hoon Park, ChungCheongNam-Do (KR)

(73) Assignee: SAMSUNG CORNING PRECISION MATERIALS CO., LTD., Gyeongsangbuk-do (KR)

(21) Appl. No.: 13/005,828

(22) Filed: Jan. 13, 2011

(30) Foreign Application Priority Data
Jan. 13, 2010 (KR) 10-2010-0003002

(51) Int. Cl. H01L 31/0224

(52) U.S. Cl. 136/256

(57) ABSTRACT

An electrode plate for a dye-sensitized photovoltaic cell includes a transparent substrate and a transparent conductive film. The transparent conductive film includes a zinc oxide thin film layer formed over the transparent substrate, the zinc oxide thin film layer being doped with gallium, and a tin oxide thin film layer formed over the zinc oxide thin film layer, the tin oxide thin film layer being doped with a dopant.

### CROSS REFERENCE TO RELATED APPLICATION

The present application claims priority from Korean Patent Application Number 10-2010-0003002 filed on Jan. 13, 2010, the entire contents of which application are incorporated herein for all purposes by this reference.

### BACKGROUND OF THE INVENTION

1. Field of the Invention

The present invention relates to an electrode plate and to a dye-sensitized photovoltaic cell having the same.

2. Description of Related Art

A photovoltaic cell is a key element in the solar power generation, in which energy from sunlight is converted directly into electricity. Photovoltaic cells are applied in various fields, including those of electrical and electronic appliances, houses, and buildings. Photovoltaic cells may be categorized by type according to the material used in the light absorbing layer thereof. Photovoltaic cells are categorized into silicon photovoltaic cells, which use silicon as the light absorbing layer; compound photovoltaic cells, which use Copper Indium Diselenide (CIS: CuInSe₂), Cadmium Telluride (CdTe), etc. as the light absorbing layer; a dye-sensitized photovoltaic cells, in which photosensitive dye is adsorbed; stacked photovoltaic cells, in which a plurality of amorphous silicon layers are stacked on one another; etc.

The dye-sensitized photovoltaic cell was invented by a team led by Professor Grätzel of the Swiss Federal Institute of Technology. Unlike the silicon photovoltaic cell, the dye-sensitized photovoltaic cell contains, as major components, a photosensitive molecular dye, which can generate electron-hole pairs by absorbing visible light, and a transition metal oxide, which conducts the electrons that are generated. Although the dye-sensitized photovoltaic cell has merits such as a low manufacturing cost compared to the silicon photovoltaic cell and applicability to the exterior windows of buildings, the glass of greenhouses, and the like, it also has a limitation on its ability to be applied in practice since its maximum photoelectric conversion efficiency is about 11% at 100 mW/cm².

In the related art, a transparent conductive film that is used as front and rear electrode plates of the dye-sensitized photovoltaic cell is made of Fluorine-doped Tin Oxide (FTO). The front electrode plate used for the photovoltaic cell is typically required to have excellent light transmissivity, electrical conductivity, heat resistance, and moisture resistance characteristics. The rear electrode plate is required to exhibit excellent electrical conductivity, heat resistance, and moisture resistance characteristics.

However, the FTO film, which is used as the front and rear electrode plates, has low electrical conductivity, despite exhibiting excellent thermal stability and surface texturing characteristics. Accordingly, the FTO film has to be 700 nm thick or thicker in order to obtain required electrical conductivity and this requirement entails a problem of high manufacturing cost. Furthermore, since the light transmissivity of the FTO film is lower than that of an Indium Tin Oxide (ITO) or zinc oxide (ZnO)-based transparent conductive film, the photoelectric conversion efficiency of the photovoltaic cell is disadvantageously low.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide an electrode plate and a dye-sensitized photovoltaic cell having the same, which exhibits excellent electrical conductivity, thermal stability, and photoelectric conversion efficiency characteristics.

Also provided are an electrode plate and a dye-sensitized photovoltaic cell having the same which can reduce the manufacturing cost.

In an aspect of the present invention, the electrode plate for a dye-sensitized photovoltaic cell includes a transparent substrate and a transparent conductive film. The transparent conductive film includes a zinc oxide thin film layer formed over the transparent substrate, the zinc oxide thin film layer being doped with gallium, and a tin oxide thin film layer formed over the zinc oxide thin film layer, the tin oxide thin film layer being doped with a dopant.

In an embodiment of the invention, the transparent conductive film may have a thickness ranging from 500 nm to 700 nm.

In another embodiment of the invention, the transparent conductive film may have a variation in sheet resistance that ranges from −20% to +20% after the transparent conductive film is heat-treated at a temperature ranging from 400° C. to 500° C.

According to exemplary embodiments of the invention, the transparent conductive film is configured such that it includes the Ga-doped zinc oxide (GZO) thin film layer and the dopant-doped thin oxide thin film layer which is formed over the zinc oxide thin film layer. Thereby, the transparent conductive film has advantageous effects in that the electrical conductivity, thermal stability, and photoelectric conversion efficiency thereof are improved.

In addition, the electrode plate for a dye-sensitized photovoltaic cell is advantageous in that manufacturing costs are reduced, since it can be formed to a thickness ranging from 500 nm to 700 nm.

Furthermore, the electrode plate for a dye-sensitized photovoltaic cell has an advantageous effect in that the transparent conductive film is not easily deteriorated when subjected to heat-treatment at a temperature ranging from 400° C. to 500° C.

The methods and apparatuses of the present invention have other features and advantages which will be apparent from, or are set forth in more detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a diagram showing a dye-sensitized photovoltaic cell according to an exemplary embodiment of the invention; and

FIG. 2 is a graph showing the photocurrent (I)-voltage (V) characteristics of a dye-sensitized photovoltaic cell to which an electrode plate according to an exemplary embodiment of the invention is applied.

### DETAILED DESCRIPTION OF THE INVENTION

The present invention will now be described more fully hereinafter with reference to the accompanying drawings, in which exemplary embodiments thereof are shown, so that this disclosure will fully convey the scope of the present invention to those skilled in the art.

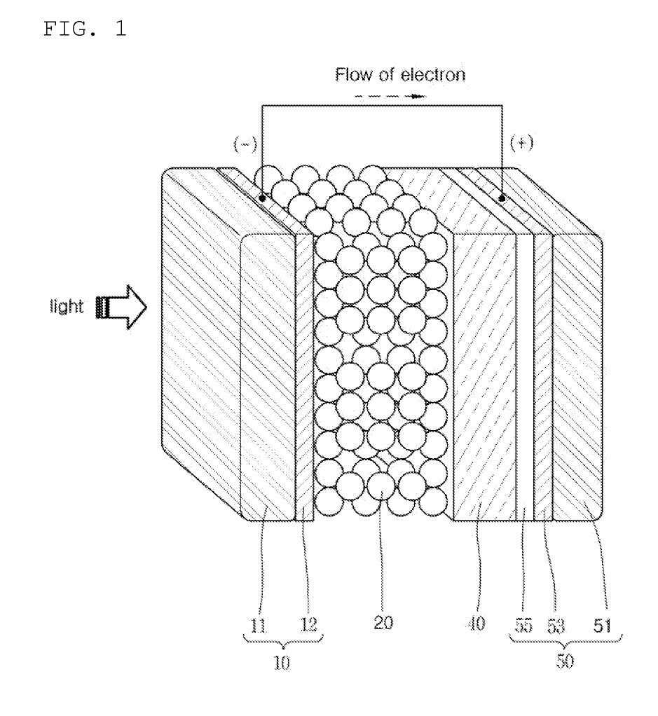

A dye-sensitized photovoltaic cell according to an exemplary embodiment of the invention is shown in FIG. 1. As shown in FIG. 1, the dye-sensitized photovoltaic cell of this embodiment includes a front electrode plate 10, a light-absorbing layer 20, an electrolyte layer 40, and a rear electrode plate 50.

The electrode plate 10 has a transparent substrate 11 and a transparent conductive film 12, which is layered over the transparent substrate 11. The transparent substrate 11 can be a glass substrate that has a thickness of 5 mm or less and a light transmissivity of 90% or more. As an alternative, the transparent substrate 11 can be made of Polyethylene Terephthalate (PET), Polyethylene Naphthalate (PEN), Polycarbonate (PC), Triacetyl Cellulose (TAC), or the like.

The transparent conductive film 12 is formed over the transparent substrate 11, and may be an Indium Tin Oxide (ITO) film, a Fluorine-doped Tin Oxide (FTO) film, or Gallium-doped Zinc Oxide (GZO) film. As described above, the FTO film has the drawbacks of low electrical conductivity and low transmissivity. Although the ITO film is known to have excellent electrical conductivity and transmissivity, it has low price competitiveness and its thermal stability deteriorates in the process of performing heat-treatment (generally 500° C.) after TiO₂ particles are coated thereon. Therefore, the intended efficiency of the photovoltaic cell cannot be obtained by using the ITO film, or the efficiency is limited. In addition, although the GZO thin film has excellent electrical conductivity and light transmissivity characteristics, its photoelectric conversion efficiency is lower than that of the FTO film, since, when it is used as a front electrode, interfacial bonding characteristics between the GZO thin film and the dye adsorbed TiO₂ is bad.

In an exemplary embodiment, the transparent conductive film 12 is formed such that it includes the GZO thin film layer, which has high electrical conductivity and high light transmissivity, and a dopant-doped tin oxide (SnO₂) thin film layer, which is formed over the GZO thin film layer, the tin oxide thin film layer having excellent thermal stability and interfacial bonding characteristics with TiO₂. In an example, the dopant is added to the tin oxide thin film layer in an amount ranging from 1 wt % to 10 wt %, and can be one selected from among Sb, Zn, and Nb.

The thickness of the transparent conductive film 12 can be in the range from 500 nm to 1500 nm and, preferably, from 500 nm to 700 nm. It is preferred to form a GZO thin film, followed by chemical etching using a weak acid or weak alkali such that the transparent conductive film 12 has texture on the surface thereof and thereby has a haze value ranging from 1% to 30%. If the haze value exceeds 30%, transmissivity is lowered, which makes it difficult to harvest light (or collect light).

The sheet resistance of the transparent conductive film 12 is 15Ω per unit area or less, and preferably from 2Ω to 5Ω per unit area. In an example, the transparent conductive film 53 is characterized in that the variation in its sheet resistance is within the range from −20% to +20% even after it is heat-treated at a temperature ranging from 400° C. to 500° C.

The light-absorbing layer 20 includes semiconductor particles and light-sensitive dye. The light-sensitive dye is adsorbed onto the semiconductor particles and its electrons are excited when it absorbs visible light. The semiconductor particles can be made not only of a simple semiconductor, of which silicon is representative, but also of a metal oxide, a metal oxide composite having a perovskite structure, or the like. Here, it is preferred that the semiconductor be an n-type semiconductor in which electrons in conduction band act as carriers to provide anode current when excited by light. In a specific example, the semiconductor particles can be made of at least one selected from among TiOx, WOx, SnOx, and ZnOx. The types of the semiconductor particles are not limited thereto, but the above elements can be used alone or in mixtures of two or more thereof.

In addition, it is preferred that the semiconductor particles have a large surface area such that the dye adsorbed on the surface of the semiconductor particles can absorb more light. Therefore, it is preferable for the semiconductor particles to have an average particle diameter of 50 nm or less, and more preferably from 15 nm to 25n. A particle diameter exceeding 50 nm is undesirable, since the reduced surface area may lower the catalytic efficiency.

Although the type of the dye is not limited as long as it can be generally used in the field of photovoltaic cells or photoelectric cells, ruthenium (Ru) complexes are preferable. Available examples of the Ru complexes may include, but are not limited to, RuL₂(SCN)₂, RuL₂(H2O)₂, RuL₃, RuL₂, etc., where L indicates 2,2′-bipyridyl-4,4′-Dicarboxylate. Available examples other than the Ru complexes may include, but not limited to, xanthine colorants such as rhodamine B, Rose Bengal, eosin, and erythrocin; cyanine colorants, such as quinocyanine and cryptocyanine; alkaline dyes, such as phenosafranine, Capri Blue, thiosin, and Methylene Blue; porphyrin compounds, such as chlorophyll, Zn porphyrin, and Mg porphyrin; azo colorants; phthalocyanine compounds; complex compounds such as Ru tris-bipyridyl; anthraquinone colorants; polycyclic quinine colorants; etc. These substances can be used alone or in mixtures of two or more thereof.

The electrolyte layer 40 is made of electrolyte. The electrolyte is made of iodine-based oxidation/reduction pairs (I⁻/I₃⁻), and serves to receive electrons from the rear electrode plate 50 and conduct the electrons to the dye by oxidation/reduction. Here, the open circuit voltage is determined by the difference between the energy level of the dye and the oxidation/reduction level of the electrolyte. The electrolyte is uniformly dispersed between the front electrode plate 10 and the rear electrode plate 50, and can infiltrate into the light-absorbing layer 20. The electrolyte can be made of, for example, a solution formed by dissolving iodine in acetonitrile, but this is not intended to be limiting. Any substance that has a hole conduction function can be used without limitation.

The rear electrode substrate 50 includes a transparent substrate 51 and a transparent conductive film 53 formed over the transparent substrate 51. The thickness of the transparent substrate 51 may be 5 mm or less, and a glass substrate having a light transmissivity of 90% or more can be used. Other available examples may include, but not limited to, Polyethylene Terephthalate (PET), Polyethylene Naphthalate (PEN), Polycarbonate (PC), Triacetyl Cellulose (TAC), or the like.

The transparent conductive film 53 can be a GZO thin film layer having high electrical conductivity and high light transmissivity, or can be configured such that it includes the GZO thin film and a dopant-doped tin oxide (SnO₂) thin film layer formed over the GZO thin film, the tin oxide thin film layer. In an example, the dopant added to the tin oxide (SnO₂) accounts for 1 wt % to 10 wt % of the total weight, and can be one selected from among Sb, Zn, and Nb.

The transparent conductive film 53 can be formed by sputtering to a thickness ranging from 500 nm to 1500 nm and preferably from 500 nm to 700 nm. The sheet resistance of the transparent conductive film 53 may be 15Ω per unit area or less, and preferably from 2Ω to 5Ω per unit area. In an example, the transparent conductive film 53 is characterized in that the variation in its sheet resistance is within the range from −20% to +20% even after it is heat-treated at a temperature ranging from 400° C. to 500° C.

As shown in FIG. 1, the rear electrode plate 50 can also include a catalyst layer 55, which is formed over the transparent conductive film 53 in order to increases the rate of oxidation/reduction of the electrolyte layer 40. The catalyst layer 55 can be made of one selected from among Pt, Au, C, and Rb. In an example, it is preferred that the catalyst layer 55 be platinum black if it is made of Pt or be porous carbon if it is made of C. The platinum black can be formed from Pt by anodizing, chloroplatinic acid treatment, or the like, and the porous carbon can be formed by, for example, sintering carbon particles or heat-treating organic polymer.

When sunlight enters the dye-sensitized photovoltaic cell of this embodiment, photons are first absorbed by dye molecules inside the light-absorbing layer 20 so that the dye molecules undergo electron transition from the ground state to the excited state, thereby forming electron-hole pairs. Electrons in the excited state are injected into the conduction band at the interface of the semiconductor particle, and the injected electrons are carried to the front electrode plate 10 through an interface. Afterwards, the electrons travel to the rear electrode plate 50 through an outer circuit. In the meantime, the dye, which is oxidized as the result of electron transition, is reduced by oxidation-reduction ions inside the electrolyte 40, and the oxidized ions is reduced by the electrons that have arrived at the interface of the rear electrode substrate 50 in order to establish charge neutrality, by which the dye-sensitized photovoltaic cell operates.

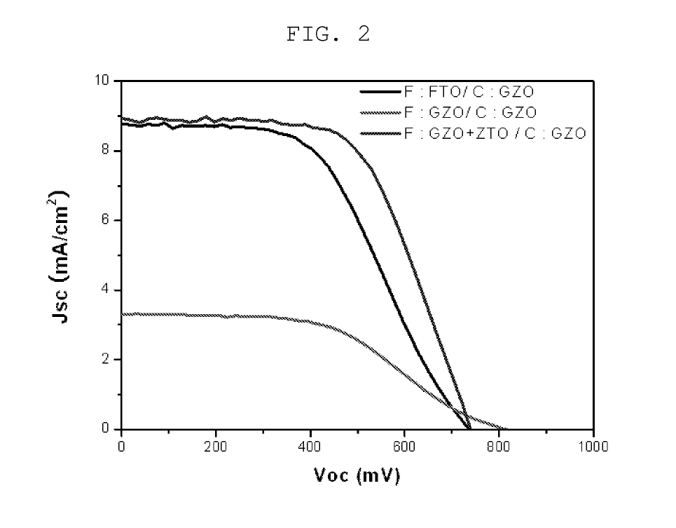

FIG. 2 is a graph showing photocurrent (I)-voltage (V) characteristics of a dye-sensitized photovoltaic cell to which an electrode plate according to an exemplary embodiment of the invention is applied.

From the photocurrent (I)-voltage (V) curve of FIG. 2, short-circuit current (Jsc), open circuit voltage (Voc), fill factor (FF), and photoelectric conversion efficiency (η) are presented in Table 1 below.

TABLE 1

| | Front (F) and | | | | |
|---|---|---|---|---|---|
| | rear (C) | Voc | Jsc | F.F | η |
| | electrode plate | (mV) | (mA/cm²) | (%) | (%) |
| Example | F: GZO + ZTO, | 739.257 | 8.923 | 60.42 | 3.99 |
| | C: GZO | | | | |
| Comp. Example 1 | F: FTO, C: GZO | 735.843 | 8.763 | 51.26 | 3.31 |
| Comp. Example 2 | F: GZO, C: GZO | 814.343 | 3.298 | 48.77 | 1.31 |

Example indicates a dye-sensitized photovoltaic cell in which a transparent conductive film, which is produced by forming a GZO film over a transparent substrate by sputtering a zinc oxide target doped with Ga in an amount of 2.5 mol % (i.e. a GZO target) and forming a film over the GZO film by sputtering a tin oxide (SnO₂) target doped with niobium oxide (Nb₂O₅) in an amount of 5 wt %, was used as a front electrode. A transparent conductive film, which is produced over a transparent substrate by sputtering a zinc oxide target doped with Ga in an amount of 2.5 mol % (i.e. a GZO target), was used as a rear electrode.

Comparative Example 1 is a dye-sensitized photovoltaic cell in which an FTO substrate was used as a front electrode substrate and a transparent conductive film, which is formed over a transparent substrate by sputtering a zinc oxide target doped with Ga in an amount of 2.5 mol % (i.e. a GZO target), was used as a rear electrode. Comparative Example 2 is a dye-sensitized photovoltaic cell in which transparent conductive films, each of which is formed over a transparent substrate by sputtering a zinc oxide target doped with Ga in an amount of 2.5 mol % (i.e. a GZO target), were used as a front electrode and a rear electrode.

Here, it can be appreciated that the photoelectric conversion efficiency (η) of Comparative Example 2, in which the GZO films were used as the front and rear electrodes, is lower than that of Comparative Example 1. This is because the GZO film does not have a good interfacial bonding characteristic with TiO₂ onto which a dye is adsorbed.

Referring to FIG. 2 and Table 1, it can be appreciated that the photocurrent and the photoelectric conversion efficiency (η) of the cell exhibited by the dye-sensitized photovoltaic cell according to Example is improved compared to those of Comparative Examples 1 and 2. This is because TiO₂, onto which a dye is adsorbed, is not in contact with the GZO thin film but is in contact with the tin oxide (SnO₂) thin film, which has excellent thermal stability and an excellent interfacial bonding characteristic with TiO₂.

The foregoing descriptions of specific exemplary embodiments of the present invention have been presented for the purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. An electrode plate for a dye-sensitized photovoltaic cell, comprising:
a transparent substrate; and
a transparent conductive film, wherein the transparent conductive film includes a zinc oxide thin film layer formed over the transparent substrate, the zinc oxide thin film layer being doped with gallium, and a tin oxide thin film layer formed over the zinc oxide thin film layer, the tin oxide thin film layer being doped with a dopant.

2. The electrode plate according to claim 1, wherein the electrode plate is a front electrode plate of the dye-sensitized photovoltaic cell.

3. The electrode plate according to claim 1, wherein the dopant of the tin oxide thin film layer is one selected from a group consisting of Sb, Zn, and Nb.

4. The electrode plate according to claim 1, wherein the transparent conductive film has a thickness ranging from 500 nm to 700 nm.

5. The electrode plate according to claim 1, wherein the transparent conductive film has a sheet resistance ranging from 2Ω to 5Ω per unit area.

6. The electrode plate according to claim 5, wherein the transparent conductive film has a variation in sheet resistance that ranges from −20% to +20% after the transparent conductive film is heat-treated at a temperature ranging from 400° C. to 500° C.

7. The electrode plate according to claim 1, wherein the electrode plate is a rear electrode plate of the dye-sensitized photovoltaic cell,
the electrode plate further comprising a catalyst layer formed over the transparent conductive film to promote oxidation/reduction of electrolyte.

8. The electrode plate according to claim 7, wherein the catalyst layer is made of one selected from Pt, Au, C, and Rb.

9. A dye-sensitized photovoltaic cell comprising an electrode plate, wherein the electrode plate comprises:
a transparent substrate; and
a transparent conductive film, wherein the transparent conductive film includes a zinc oxide thin film layer formed over the transparent substrate, the zinc oxide thin film layer being doped with gallium, and a tin oxide thin film layer formed over the zinc oxide thin film layer, the tin oxide thin film layer being doped with a dopant.
